(19) United States
(12) Patent Application Publication
(10) Pub. No.: US 2024/0018656 A1
(43) Pub. Date: Jan. 18, 2024

(54) FLOW CONTROL ARRANGEMENTS WITH ENCLOSED FLOW SWITCHES AND ISOLATION VALVES, SEMICONDUCTOR PROCESSING SYSTEMS, AND FLOW CONTROL METHODS

(71) Applicant: ASM IP Holding, B.V., Almere (NL)

(72) Inventors: Glenn Holbrook, Scottsdale, AZ (US); Mark Fessler, Phoenix, AZ (US)

(21) Appl. No.: 18/351,227

(22) Filed: Jul. 12, 2023

Related U.S. Application Data
(60) Provisional application No. 63/389,790, filed on Jul. 15, 2022.

(51) Int. Cl. C23C 16/455; G05D 7/06

(52) U.S. Cl. CPC C23C 16/45561; G05D 7/0647

(57) ABSTRACT

A flow control arrangement includes a housing, an isolation valve, and a flow switch. The housing seats an inlet conduit and an outlet conduit. The isolation valve is arranged in the housing and is connected to the inlet conduit. The flow switch is arranged in the housing, is connected to the isolation valve, and fluidly couples the outlet conduit to the isolation valve. The flow switch further has a shutoff trigger and is operatively connected to the isolation valve to close the isolation valve when flow traversing the isolation valve is greater than the shutoff trigger. Semiconductor processing systems and flow control methods are also provided.

### CROSS-REFERENCE TO RELATED APPLICATION(S)

This application claims the benefit of U.S. Provisional Application 63/389,790 filed on Jul. 15, 2022, the entire contents of which are incorporated herein by reference.

### FIELD OF INVENTION

The present disclosure generally relates to controlling fluid flows. More particularly, the present disclosure relates to controlling the fluid flows in semiconductor processing systems, such as the flow of fluids in semiconductor processing systems employed to deposit films onto substrates during the fabrication of semiconductor devices.

### BACKGROUND OF THE DISCLOSURE

Semiconductor processing systems, such as semiconductor processing systems employed to deposit material layers onto substrates during the fabrication of semiconductor devices, commonly employ fluid flows during semiconductor device fabrication. In some semiconductor processing operations, the fluids may contain hazardous materials. For example, semiconductor processing systems employed to deposit material layers onto substrates may employ fluids containing materials known to be hazardous to human health, are flammable, and/or which are corrosive. Semiconductor processing systems may also issue exhaust flows containing hazardous materials, such as a residual material layer precursor and/or reaction products generated during the processing operation. To ensure safety, semiconductor processing systems therefore typically include countermeasures effective to limit (or eliminate) risks associated with fluid flows containing hazardous materials during processing. For example, flow control devices employed to control the flow of fluids containing hazardous materials are generally housed within an enclosure—and the enclosure ventilated using a vent flow to remove hazardous material from within the enclosure in the unlikely event that fluids leaks from the flow control device during process. For similar reasons inert gases and/or diluents are generally intermixed into exhaust flows containing flammable and/or corrosive materials issued by semiconductor processing systems during semiconductor processing.

Typically, the flow rate of the vent flow provided to a flow control device is sized according to the maximum flow rate of the hazardous material possible through the flow control device. This ensures risk mitigation in the event that the flow control device fails in a fully open position. The same holds true for the flow rate of inert gas and diluents provided to exhaust flows, which are also typically sized according to maximum flow of the hazardous material that could be present in the exhaust flow based on the flow rating of the flow control device providing the fluids responsible for the hazardous material in the exhaust flow. While generally satisfactory insofar of limiting the risks attendant to the hazardous material provided and/or generated during processing, oversizing the vent flow, the inert gas flow, and/or the diluent flow in relation to the flow rate required by the actual processing performed by the semiconductor processing system increases the cost associated with the processing. Oversizing the inert gas flow provided to the exhaust flow and/or the diluent flow provided to the exhaust flow may also increases emissions of materials potentially harmful to the environment, such nitrogen oxide emissions, to levels beyond that necessary given the processing actually performed by the semiconductor processing system.

Such systems and methods have generally been considered suitable for their intended purpose. However, there remains a need in the art for improved flow control arrangements, semiconductor processing systems having flow control arrangements, and flow control methods. The present disclosure provides a solution to this need.

### SUMMARY OF THE DISCLOSURE

A flow control arrangement is provided. A flow control arrangement includes a housing, an isolation valve, and a flow switch. The housing seats an inlet conduit and an outlet conduit. The isolation valve is arranged in the housing and is connected to the inlet conduit. The flow switch is arranged in the housing, is connected to the isolation valve, and fluidly couples the outlet conduit to the isolation valve. The flow switch further has a shutoff trigger and is operatively connected to the isolation valve to close the isolation valve when flow traversing the isolation valve is greater than the shutoff trigger.

In addition to one or more of the features described above, or as an alternative, further examples may include that the housing of the flow control arrangement includes a tamperproof body enclosing the isolation valve and the flow switch.

In addition to one or more of the features described above, or as an alternative, further examples may include of the flow control arrangement may include a relay and a solenoid. The relay may be arranged outside of the housing and operatively associated with the flow switch. The solenoid may be electrically connected to the relay and arranged in the housing. The solenoid may eb operatively connected to the isolation valve to close the isolation valve when flow rate of a fluid traversing the flow switch is greater than the shutoff trigger.

In addition to one or more of the features described above, or as an alternative, further examples of the flow control arrangement may include an internal communication harness, an electrical connector, an external communication cable, and a controller. The internal communication harness is arranged in the housing, is connected to the isolation valve, and is further connected to the flow switch. The electrical connector is connected to the internal communication harness and is seated in a wall of the housing. The external communication cable is arranged outside of the housing and is connected to the electrical connector. The controller is connected to the external communication cable and operably connects the flow switch to the isolation valve through the external communication cable, the electrical connector, and the internal communication harness.

In addition to one or more of the features described above, or as an alternative, further examples of the flow control arrangement may include a controller arranged outside of the housing and operably connecting the flow switch to the isolation valve.

In addition to one or more of the features described above, or as an alternative, further examples of the flow control arrangement may include that the controller includes a safety programmable logic controller device.

In addition to one or more of the features described above, or as an alternative, further examples may include that the controller includes a processor disposed in communication with a memory having a non-transitory machine-readable medium with a plurality of program modules recorded thereon containing instructions. The instructions may cause the processor to receive a shutoff signal from the flow switch and provide a closure signal to the isolation valve upon receipt of the shutoff signal from the flow switch.

In addition to one or more of the features described above, or as an alternative, further examples may include that the isolation valve is a first an isolation valve and that the flow control arrangement incudes a second isolation valve. The second isolation valve may be arranged in the housing and couple the first isolation valve to the outlet conduit. The second isolation valve may be operably associated with the flow switch.

In addition to one or more of the features described above, or as an alternative, further examples may include a first relay, a first solenoid, a second relay, and a second solenoid. The first relay may be arranged outside of the housing and operatively associated with the flow switch. The first solenoid may be electrically connected to the relay, arranged in the housing, and operatively connected to the first isolation valve to close the first isolation valve when the flow rate of the fluid traversing the flow switch is greater than the shutoff trigger. The second relay may be arranged outside of the housing and operatively associated with the flow switch. The second solenoid may be electrically connected to the second relay, arranged in the housing, and operatively connected to the second isolation valve to close the second isolation valve when the flow ate of the fluid traversing the flow switch is greater than the shutoff trigger.

In addition to one or more of the features described above, or as an alternative, further examples may include that the flow control arrangement includes an internal communication harness, an electrical controller, an external communication cable, and a controller. The internal communication harness may be arranged in the housing and connected to the first isolation valve, the flow switch, and the second isolation valve. The electrical connector may be connected to the internal communication harness and seated in a wall of the housing. The external communication cable may be connected to the electrical connector and arranged outside of the housing. The controller may be connected to the external communication cable and operably connect the flow switch to the first isolation valve and the second isolation valve.

In addition to one or more of the features described above, or as an alternative, further examples may include that controller has processor disposed in communication with a memory having a non-transitory machine-readable medium with a plurality of program modules recorded on memory containing instructions. The instructions may cause the processor to the processor to receive a shutoff signal from the flow switch, provide a first closure signal to the first isolation valve upon receipt of the shutoff signal from the flow switch, and provide a second closure signal to the second isolation valve upon receipt of the shutoff signal from the flow switch.

In addition to one or more of the features described above, or as an alternative, further examples may include that the flow switch is a first flow switch and that the flow control arrangement further includes a second flow switch. The second flow switch may couple the first flow switch to the outlet conduit and be operably connected to the isolation valve.

In addition to one or more of the features described above, or as an alternative, further examples may include that shutoff trigger is a first shutoff trigger and the second flow switch has a second shutoff trigger. The second shutoff trigger may be substantially equivalent to the first shutoff trigger.

In addition to one or more of the features described above, or as an alternative, further examples may include that the shutoff trigger is a first shutoff trigger and that the second flow switch has a second shutoff trigger. The second shutoff trigger is different, e.g., may be greater than of less than, from the first shutoff trigger.

In addition to one or more of the features described above, or as an alternative, further examples of the flow control arrangement may include a controller arranged outside of the housing. The controller may operably connect the first flow switch and the second flow switch to the isolation valve.

In addition to one or more of the features described above, or as an alternative, further examples of the flow control arrangement may include that the isolation valve is a first isolation valve, the flow switch is a first flow switch, and that the flow control arrangement further includes a second flow switch and a second isolation valve. The second flow switch may be connected to the first flow switch and coupled by the first flow switch to the first isolation valve. The second isolation valve may be connected to the second flow switch and coupled by the second flow switch to the first flow switch. The outlet conduit may be connected to the second isolation valve, the second isolation valve may couple the outlet conduit to the second flow switch, and the second flow switch may be operably connected to at least one of the first isolation valve and the second isolation valve.

In addition to one or more of the features described above, or as an alternative, further examples of the flow control arrangement may include that the first flow switch is operably connected to both the first isolation valve and the second isolation valve, and that the second flow switch is operably connected to both the first isolation valve and the second isolation valve.

In addition to one or more of the features described above, or as an alternative, further examples of the flow control arrangement may include one of the first flow switch and the second flow switch is operably connected to only one of the first isolation valve and the second isolation valve.

A semiconductor processing system is provided. The semiconductor processing system includes a gas box, a flow control arrangement as described above, a process chamber and a fluid source. The gas box includes a flow control device with a flow rating. The flow control arrangement is arranged outside of the gas box and the flow control device is connected to the outlet conduit, and therethrough to the inlet conduit of the flow control arrangement. The process chamber includes and is fluidly couples to the flow control arrangement through the flow control device. The fluid source includes a hazardous process material, is connected to the inlet conduit of the flow control arrangement, and is connected the flow control arrangement to the process chamber.

In addition to one or more of the features described above, or as an alternative, further examples of the semiconductor processing system may include a vent source connected to the gas box and providing a vent flow to the gas box. The vent flow may be undersized relative to the flow rating of the flow control device.

In addition to one or more of the features described above, or as an alternative, further examples of the semiconductor processing system may include an exhaust source and an inert/diluent fluid source. The exhaust source may be connected to the process chamber and receive an exhaust flow from the process chamber. The inert/diluent fluid source may be connected exhaust source and provide an inert/diluent fluid to the exhaust flow. An inert/diluent fluid flow rate of the inert/diluent fluid provided to the exhaust flow may be undersized relative to the flow rating of the flow control device.

A flow control method is provided. The flow control method includes, at a flow control arrangement as described above, receiving a flow of a fluid including a hazardous process material (HPM) at the inlet conduit and comparing flow rate of the fluid to the shutoff trigger. When the flow rate of the fluid is less than the shutoff trigger, the flow control arrangement flows from the inlet conduit to the outlet conduit through the isolation valve and the flow switch. When the flow rate of the fluid is greater than the shutoff trigger the flow control arrangement fluidly separates the outlet conduit from the inlet conduit using the isolation valve. It is contemplated that the shutoff trigger be less than a flow rating of a flow control device coupling the outlet conduit to a semiconductor processing system. It is also contemplated that at least one of the vent flow provided to a gas box of the semiconductor processing system and/or an inert/diluent fluid provided to an exhaust flow issued by process chamber of the semiconductor processing system be undersized relative to a flow rating of a flow control device arranged in the gas box and fluidly coupling the flow control arrangement to the process chamber.

In addition to one or more of the features described above, or as an alternative, further examples of the flow control method may include closing only one of a first isolation valve and a second shutoff coupling the inlet conduit to the outlet conduit when the flow rate of the fluid is greater than the shutoff trigger.

In addition to one or more of the features described above, or as an alternative, further examples of the flow control method may include closing both one of a first isolation valve and a second shutoff coupling the inlet conduit to the outlet conduit when the flow rate of the fluid is greater than the shutoff trigger.

In addition to one or more of the features described above, or as an alternative, further examples of the flow control method may include comparing the flow rate of the fluid to a first shutoff trigger and a second shutoff trigger, and closing the isolation valve when the flow rate is greater than only one of the first shutoff trigger and the second shutoff trigger.

In addition to one or more of the features described above, or as an alternative, further examples of the flow control method may include comparing the flow rate of the fluid to a first shutoff trigger and a second shutoff trigger, and closing the isolation valve when the flow rate is greater than both the first shutoff trigger and the second shutoff trigger.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of the semiconductor processing system with a flow control arrangement in accordance with the present disclosure, showing the flow control arrangement connecting a fluid source a gas box in the system;

FIGS. 2 and 3 are schematic views of the flow control arrangement of FIG. 1 according to a first example of the present disclosure, showing a singular flow switch and a singular isolation valve connecting the fluid source to the semiconductor processing system;

FIGS. 4-7 are schematic views of the flow control arrangement of FIG. 1 according to a second and a third example of the present disclosure, showing flow control arrangements having serially arranged flow switches and isolation valves according to the examples;

FIGS. 8 and 9 are schematic views of the flow control arrangement of FIG. 1 according to a fourth example of the present disclosure, showing redundant flow switches and isolation valves connecting the fluid source to the semiconductor processing system; and

FIG. 10 is a block diagram of a flow control method according to the present disclosure, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

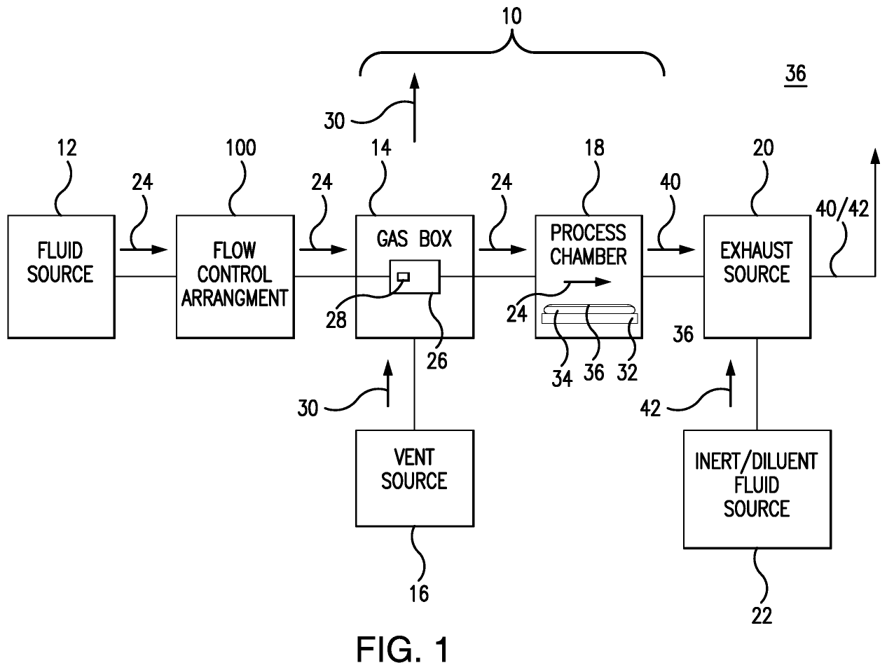

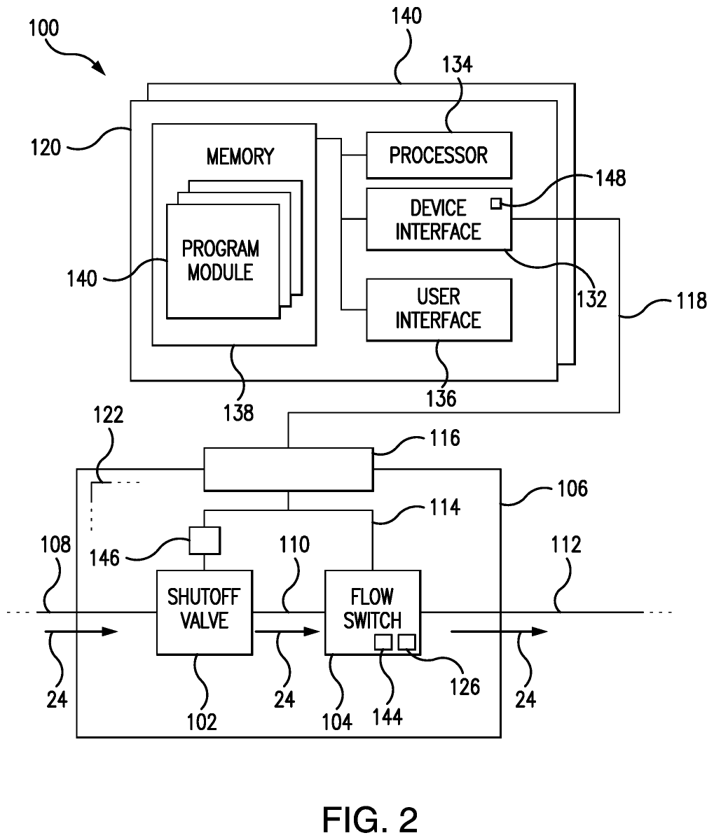

Reference will now be made to the drawings wherein like reference numerals identify similar structural features or aspects of the subject disclosure. For purposes of explanation and illustration, and not limitation, a partial view of an example of a semiconductor processing system with a flow control arrangement in accordance with the present disclosure is shown in FIG. 1 and is designated generally by reference character 100. Other examples of flow control arrangements, semiconductor processing systems having flow control arrangements, and flow control methods in accordance with the present disclosure, or aspects thereof, are provided in FIGS. 2-10, as will be described. The systems and methods of the present disclosure may be used to control flow of fluids to semiconductor processing systems, such as fluids containing hazardous process materials (HPMs) to semiconductor processing systems employed to deposit material layers onto substrates during the fabrication of semiconductor devices, though the present disclosure is not limited to any particular type of fluid or to semiconductor processing systems in general.

As used herein, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers in various shapes and sizes. Substrates may be made from materials including silicon, silicon germanium, silicon oxide, gallium arsenide, gallium nitride, and silicon carbide by way of example and not for limitation.

As used herein, the term “HPM” refers to a solid, liquid, or gas associated with semiconductor device fabrication that has a degree-or-hazard rating of 3 or 4 in health, flammability, instability, or water reactivity in accordance with NFPA 704 (“Standard System for the Identification of the Hazards of Materials for Emergency” 2022 Edition). HPMs may be used directly in research, laboratory, or production processes associated with semiconductor device fabrication. HPMs may be an effluent generated in connection with research, laboratory, or production processes associated with semiconductor device fabrication. HPMs may be associated with the fabrication of a semiconductor device which, as an end product, is not itself hazardous.

Referring to FIG. 1, a semiconductor processing system 10 is shown. The semiconductor processing system 10 includes a fluid source 12, the flow control arrangement 100, and a gas box 14. The semiconductor processing system 10 also includes a vent source 16, a process chamber 18, an exhaust source 20, and an inert/diluent fluid source 22. Although a particular type of semiconductor processing system is shown in FIG. 1 and described herein, it is to be understood and appreciated that other types of apparatus including semiconductor processing systems adapted for operations other than material layer deposition operations may also benefit from the present disclosure.

The fluid source 12 is connected to the flow control arrangement 100 and includes a fluid 24. The fluid 24 may include a liquid, a gas, or a mixture of liquid and a gas. In certain examples, the fluid may include a material layer precursor. In accordance with certain examples, the fluid 24 may include an HPM such as a material known to be hazardous to human health, is flammable or pyrophoric, and/or which may be corrosive. Examples of hazardous materials that may be included in the fluid 24 include hydrogen (H 2) gas, hydrochloric acid (HCl), silane (SiH₄), dichlorosilane (H₂SiCl₂), and/or trichlorosilane (HCl₃Si).

The gas box 14 houses a flow control device 26 and is connected to the vent source 16. The gas box 14 further connects the flow control arrangement 100 to the process chamber 18 and is in turn connected to the vent source 16. The flow control device 26 has a flow rating 28 (e.g., a maximum volumetric or mass flow rate) and in turn fluidly couples the flow control arrangement 100, and therethrough the fluid source 12, to the process chamber 18. The vent source 16 is connected to the gas box 14 and is configured to draw a vent flow 30 from within an interior of the gas box 14. In certain examples, the vent source 16 may be configured to make up the vent flow 30 using a secondary flow drawn (at least in part) from the environment external to the gas box 14. In such examples the vent flow 30 may comprise cleanroom air forming the make-up secondary vent flow drawn from a cleanroom environment housing the semiconductor processing system 10 is located. As will be appreciated by those of skill in the art in view of the present disclosure, the vent flow 30 removes the fluid 24 from within the interior of the gas box 14 in the unlikely event that the flow control device 26 develops a leak. It is contemplated that the flow control device 26 may include one or more of the metering valve, an orifice plate, and/or a mass flow controller device.

The process chamber 18 is connected to the gas box 14, couples the gas box 14 to the exhaust source 20, and houses a substrate support 32. More specifically, the interior of the process chamber 18 is fluidly coupled to the flow control device 26 and therethrough to the fluid source 12 through the flow control arrangement 100 to provide the fluid 24 to the interior of the process chamber 18. In certain examples, the substrate support 32 may include a susceptor structure. In accordance with certain examples, the substrate support 32 may include a heater structure. It is contemplated that the substrate support 32 be configured to support a substrate 34, and that the process chamber 18 be configured to cause a material layer 36 to be deposited onto an upper surface of the substrate 34 using the fluid 24. In certain examples, the material layer 36 may be deposited using an epitaxial deposition technique. In accordance with certain examples, the material layer 36 may be deposited using an atomic layer deposition (ALD) technique. It is also contemplated that, in accordance with certain examples, the material layer 36 may be deposited using a plasma deposition technique, such as a plasma-enhanced chemical vapor deposition technique or a plasma-enhanced ALD technique.

The exhaust source 20 is connected to the process chamber 18 and fluidly couples the interior of the process chamber 18 to the external environment 38 to communicate an exhaust flow 40 (e.g., residual material layer precursor and/or reaction products), to the external environment 38. The inert/diluent fluid source 22 fluidly coupled to the exhaust flow 40, e.g., via the exhaust source 20, for introduction of an inert/diluent fluid flow 42 into the exhaust flow 40 for communication therewith to the external environment 38. In certain examples, the exhaust source 20 may include a vacuum pump. In accordance with certain examples, the exhaust source may be fluidly coupled to the external environment 38 by an abatement device, such as scrubber.

The inert/diluent fluid source 22 is connected to the exhaust source 20 and is fluidly coupled therethrough to the external environment 38. It is contemplated that the inert/diluent fluid source 22 be configured to provide the inert/diluent fluid flow 42 to the exhaust flow 40 issued by the process chamber 18. In certain examples, the inert/diluent fluid flow 42 may include (e.g., consist of or consist essentially of) nitrogen (N 2) gas, argon (Ar), helium (He), or a mixture thereof. As will be appreciated by those of skill in the art in view of the present disclosure, the inert/diluent fluid flow 42 may include other materials and remain within the scope of the present disclosure.

As has been explained above, providing the vent flow 30 to the gas box 14 and/or the inert/diluent fluid flow 42 to the exhaust flow 40 increases cost of operating the semiconductor processing system 10, typically in correspondence to the flow rate of the vent flow 30 and/or inert/diluent fluid flow 42. To limit the costs attendant with providing the vent flow 30 to the gas box 14 and/or the inert/diluent fluid flow 42 to the exhaust flow 40, the semiconductor processing system 10 includes the flow control arrangement 100. The flow control arrangement 100 is configured to limit the flow rate of at least one of the vent flow 30 provided to the gas box 14 and/or the inert/diluent fluid flow 42 provided to the exhaust flow 40 by sizing the flow rates of either (or both) according flow rate of the fluid 24 actually employed to deposit the material layer 36 onto the substrate 34—and not the flow rating 28 of the flow control device 26—while providing a predetermined safety integrity level (SIL). As will be appreciated by those of skill in the art in view of the present disclosure, limiting the flow rate of the inert/diluent fluid flow 42 introduced into the exhaust flow 40 may further limit the amount of environmentally harmful material introduced into the external environment 38 by the semiconductor processing system 10, for example, by limiting nitrogen oxide emissions associated by nitrogen gas introduced into the exhaust flow 40 issued by the process chamber 18.

With reference to FIG. 2, the flow control arrangement 100 is shown. The flow control arrangement 100 generally includes an isolation valve 102 and a flow switch 104. In the illustrated example the flow control arrangement 100 also includes a housing 106, an inlet conduit 108, an interconnect conduit 110, and an outlet conduit 112. As shown and described herein the flow control arrangement 100 further includes an internal communication harness 114, an electrical connector 116, and external communication cable 118, and a controller 120. Although a particular arrangement of the flow control arrangement 100 is shown in and described herein, it is to be understood and appreciated that the flow control arrangement 100 may have a different arrangement in other examples remain within the scope of the present disclosure.

The housing 106 is arranged between the fluid source 12 (shown in FIG. 1) and the gas box 14 (shown in FIG. 1) and encloses the isolation valve 102 and the flow switch 104. In certain examples the housing 106 may be arranged outside of the semiconductor processing system (shown in FIG. 1). In accordance with certain examples, the housing 106 may include a tamperproof body 122. It is also contemplated that, in accordance with certain examples, the housing 106 may be formed from a metallic material, such as stainless steel. As will be appreciated by those of skill in the art in view of the present disclosure, enclosing the flow switch 104 within the tamperproof body 122 prevents damage of the isolation valve 102 and the flow switch 104, such as during maintenance of the semiconductor processing system 10, ensuring that the flow switch reliably closes the isolation valve 102 when flow rate of the fluid traversing the flow switch 104 rises above a predetermined flow rate.

The inlet conduit 108 and the outlet conduit 112 are seated in the housing 106. The inlet conduit 108 is connected to the fluid source 12 and couples the fluid source 12 to the isolation valve 102. The isolation valve 102 is connected to the interconnect conduit 110 and couples the inlet conduit 108 to the interconnect conduit 110. The interconnect conduit 110 is connected to the flow switch 104 and couples the isolation valve 102 to the flow switch 104. The flow switch 104 is connected to the outlet conduit 112 and couples of the interconnect conduit 110 to the outlet conduit 112. It is contemplated that the gas box 14 (shown in FIG. 1), and more particularly the flow control device 26 (shown in FIG. 1) supported within the gas box 14, be connected to the outlet conduit 112 such that the flow control arrangement 100 couples the gas box 14 to the fluid source 12 for selective fluid communication of the fluid 24 to the process chamber 18 (shown in FIG. 1) using the isolation valve 102 and the flow switch 104. In certain examples the one or more of the inlet conduit 108, the interconnect conduit 110, and the outlet conduit 112 may be joined to the isolation valve 102 and/or the flow switch 104 within the housing 106 without a fitting or fastener, for example, with a welded joint or connection. As will be appreciated by those of skill in the art in view of the present disclosure, this reduces likelihood of leakage within the housing 106, improving reliability of the flow control arrangement 100.

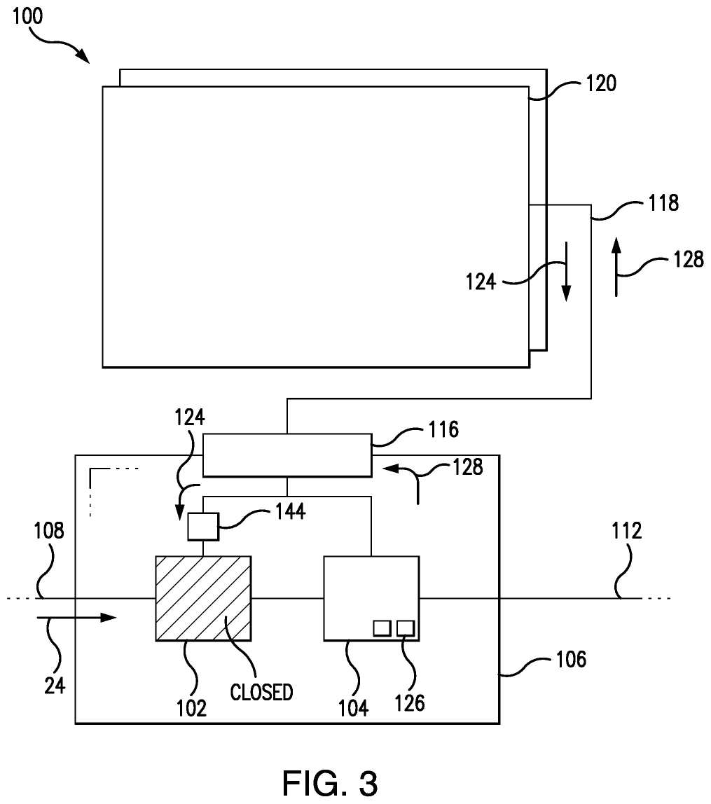

The isolation valve 102 is arranged within the housing 106 and has an open position (shown in FIG. 2) and a closed position (shown in FIG. 3). When in the open position, the isolation valve 102 fluidly couples the inlet conduit 108 to the outlet conduit 112 through the interconnect conduit 110 and the flow switch 104. When in the closed position the isolation valve 102 fluidly separates the outlet conduit 112 from the inlet conduit 108. More specifically, the isolation valve 102 fluidly separates the interconnect conduit 110 and the flow switch 104 from the inlet conduit 108 such that the fluid source 12 is fluidly separated from the flow control device 26 when the isolation valve 102 is in the closed position. It is contemplated that the isolation valve 102 be operably associated with the flow switch 104 for movement between the open position and the closed position upon receipt of a closure signal 124 (shown in FIG. 3). Examples of suitable isolation valves include D211 G1/8 DN2.0 valves, available from Jaksa d.o.o. of Ljubljana, Slovenia.

The flow switch 104 is arranged within the housing 106, has a shutoff trigger 126, and couples the isolation valve 102 to the flow control device 26 (shown in FIG. 1) to operate the isolation valve 102. The flow switch 104 further couples the isolation valve 102 to the outlet conduit 112 to close the isolation valve 102 when flow rate of the fluid 24 traversing the flow switch 104 is greater than the shutoff trigger 126. In this respect the shutoff trigger 126 defines a predetermined flow rate of the fluid 24 traversing the flow switch 104 causes the isolation valve 102 to close, which shifts the flow rate constraint of the fluid 24 to the process chamber 18 (shown in FIG. 1) from the flow control device 26 (shown in FIG. 1) to the flow control arrangement 100. In certain examples, the flow switch 104 may provide a shutoff signal 128 (shown in FIG. 3) to the controller 120 when flow of the fluid 24 traversing the flow switch 104 exceeds the shutoff trigger 126. Examples of suitable flow switches include FS10A flow switches, available from Fluid Components International LLC of San Marcos, California.

In certain examples the shutoff trigger 126 may be less than the flow rating 28 (shown in FIG. 1) of the flow control device 26 (shown in FIG. 1). As will be appreciated by those of skill in the art in view of the present disclosure, this causes the flow switch 104 to fluidly separate the fluid source 12 from the gas box 14 at a flow rate corresponding to the shutoff trigger 126, the maximum flow rate of the fluid 24 to the process chamber 18 (shown in FIG. 1) thereby being the flow rate corresponding to the shutoff trigger 126 and not the flow rating 28 of the flow control device 26. As will also be appreciated by those of skill in the art in view of the present disclosure, sizing the shutoff trigger 126 such that the shutoff trigger 126 is smaller than the flow rating 28 of the flow control device 26 limits flow rate of the vent flow of the vent flow 30 (shown in FIG. 1) and/or the inert/diluent fluid flow 42 (shown in FIG. 1) required by the semiconductor processing system 10 (shown in FIG. 1), limiting operating cost of the semiconductor processing system 10. In certain examples, the shutoff trigger 126 may correspond (e.g., be substantially equivalent) to the maximum flow rate an HPM provided to the process chamber 18 during deposition of the material layer 36 (shown in FIG. 1) onto the substrate 34 (shown in FIG. 1).

The internal communication harness 114 is arranged in the housing 106, is connected to the isolation valve 102 and the flow switch 104, and couples the isolation valve 102 and the flow switch 104 to the electrical connector 116. The electrical connector 116 is seated in a wall of the housing 106, is connected to the internal communication harness 114, and couples the internal communication harness 114 to the external communication cable 118. The external communication cable 118 is connected to the electrical connector 116 and couples the electrical connector 116 to the controller 120. In certain examples, the internal communication harness 114 and the external communication cable 118 may include discrete (i.e., electrically isolated from one another) conductors electrically connecting the controller 120 to the isolation valve 102 and the flow switch 104, potentially improving reliability by avoiding the need to position an analog-to-digital converter within the housing 106.

The controller 120 is connected to the external communication cable 118 and therethrough to the isolation valve 102 and the flow switch 104. More specifically, the controller 120 is electrically connected to the isolation valve 102 and the flow switch 104 by the external communication cable 118 and the internal communication harness 114 through the electrical connector 116, the controller 120 thereby operably connecting the flow switch 104 to the isolation valve 102. In the illustrated example the controller 120 includes a device interface 132, a processor 134, a user interface 136, and a memory 138. The device interface 132 connects the processor 134 to the isolation valve 102 and the flow switch 104, which may be through the external communication cable 118 and the internal communication harness 114 via the electrical connector 116. The processor 134 is in turn operably connected to the user interface 136 to receive user input and/or provide user output therethrough, and is disposed in communication with the memory 138. The memory 138 includes a non-transitory machine-readable medium having a plurality of program modules 140 recorded thereon containing instructions that, when read by the processor 134, cause the processor 134 to execute certain operations. Among the operations are operations of a flow control method 500, as will be described.

In certain examples, the controller 120 may include a safety programmable logic controller (PLC) device 142. In accordance with certain examples, the flow switch 104 may include a sensor 144, such as a flow rate sensor, and the controller 120 may be configured to monitor performance of the flow control arrangement 100, for example, by assessing leakage through the isolation valve 102 subsequent to closure. As will be appreciated by those of skill in the art in view of the present disclosure, performance monitoring may improve reliability of the flow control arrangement 100, potentially increasing the SIL of the flow control arrangement 100. Examples of suitable safety PLC devices include TwinSafe® safety PLC devices, available from the Beckhoff Automation GmbH & Co. KG of Verl, Germany.

In accordance with certain examples, the controller 120 may operably couple the flow switch 104 to the isolation valve 102 through a solenoid 146 and a relay 148. The solenoid 146 may arranged within the housing 106 and operably connected to a valve member, such a diaphragm element, disposed within the isolation valve 102. The relay 148 may be arranged outside of the housing 106 and electrically connected to the solenoid 146, for example, through the external communication cable 118 and the internal communication harness 114. It is contemplated that the controller 120 close the relay 148 responsive to receipt of the shutoff signal 128 from the flow switch 104. Closure of the relay 148 energizes the solenoid 146, which in turn closes the isolation valve 102. In certain examples, the solenoid 146 may be latching-type solenoid, the solenoid 146 thereby maintaining the isolation valve 102 in the closed position when the shutoff signal 130 provided by the flow switch 104 is temporal or transitory. In accordance with certain examples, closure of the relay 148 responsive to the shutoff signal 128 may be according to a nuisance trip detection filter configured to detect spurious shutoff signal events. As will be appreciated by those of the skill in the art in view of the present disclosure, such signal analysis is spurious signaling detection may improve the reliability of the flow control arrangement 100, for example, by reducing (or eliminating) nuisance tripping.

As shown in FIG. 2, it is contemplated that the flow switch 104 compares flow rate the fluid 24 traversing the flow switch 104 with the shutoff trigger 126 during processing. For example, the flow switch 104 may compare the flow rate of the fluid 24 with the shutoff trigger 126 in real time with flow of the fluid 24 during deposition of the material layer 36 (shown in FIG. 1) onto the substrate 34 (shown in FIG. 1). When the flow rate of the fluid 24 is less than the shutoff trigger 126 the flow switch 104 does not provide the shutoff signal 128 to the controller 120, the isolation valve 102 remains in the open position, and the flow control arrangement provides the fluid 24 to the process chamber 18 (shown in FIG. 1).

As shown in FIG. 3, when flow rate of the fluid 24 rises above the shutoff trigger 126, the flow switch 104 provides the shutoff signal 128 to the controller 120. Responsive to receipt of the shutoff signal 128, the controller 120 in turn provides the closure signal 124 to the isolation valve 102. Responsive to receipt of the closure signal 124, the isolation valve 102 closes. As will be appreciated by those of skill in the art in view of the present disclosure, closure of isolation valve 102 fluid separates the outlet conduit 112 from the inlet conduit 108, and flow of the fluid 24 to the process chamber 18. As will also be appreciated by those of skill in the art in view of the present disclosure, cessation of flow of the fluid 24 is independent of the flow rating 28 (shown in FIG. 1) of the flow control device 26 (shown in FIG. 1), and instead depends on the shutoff trigger 126.

In certain examples, the shutoff trigger 126 may be substantially equivalent (e.g., matched) to the flow rating 28 (shown in FIG. 1) of the flow control device 26 (shown in FIG. 1), which may improve the SIL rating of the semiconductor processing system 10 (shown in FIG. 1). In accordance with certain examples, the shutoff trigger 126 may be less than the flow rating 28 of the flow control device 26, which may improve the SIL rating of the semiconductor processing system 10 and reduce operating cost of the semiconductor processing system 10. For example, the flow rate of the vent flow 30 (shown in FIG. 1) may be undersized relative to the flow rating 28 of the flow control device 26 without increasing the hazard otherwise potentially associated with providing an undersized vent flow. Alternatively (or additionally), flow rate of the inert/diluent fluid flow 42 (shown in FIG. 1) may be undersized relative the flow rating 28 of the flow control device 26 otherwise potentially associated with providing an undersized inert/diluent.

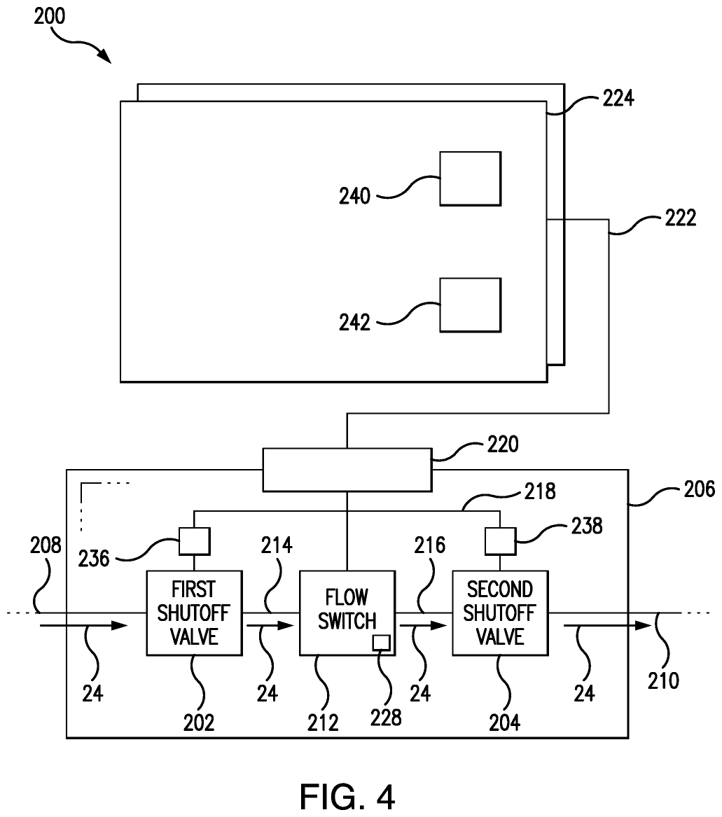

With reference to FIG. 4, a flow control arrangement 200 is shown. The flow control arrangement 200 is similar to the flow control arrangement 100 (shown in FIG. 1) and additionally includes a first isolation valve 202 and a second isolation valve 204. In the illustrated example the flow control arrangement 200 also includes a housing 206, an inlet conduit 208, an outlet conduit 210, a flow switch 212, a first interconnect conduit 214, a second interconnect conduit 216, an internal communication harness 218, and an electrical connector 220, an external communication cable 222, and a controller 224. Although a particular arrangement is shown and described herein, it is to be understood and appreciated other arrangements are possible and remain within the scope of the present disclosure.

The housing 206 seats the inlet conduit 208 and the outlet conduit 210. The housing 206 is also arranged between the fluid source 12 (shown in FIG. 1) and the gas box 14 (shown in FIG. 1) relatively to the generally direction of flow of the fluid 24 between the fluid source 12 and the gas box 14. It is contemplated that each of the first isolation valve 202, the second isolation valve 204, and the flow switch 212 be enclosed within the housing 206. In certain examples, the housing 206 may be configured to be supported outside of the semiconductor processing system (shown in FIG. 1). In accordance with certain examples, the housing 206 may include a tamperproof body 244. It is contemplated that, in certain examples, that the housing 206 may be formed from a metallic material, such as a stainless steel. It is also contemplated that, in accordance with certain examples, the housing 206 may include a weldment. As will be appreciated by those of skill in the art in view of the present disclosure, the tamperproof body 122 may limit (or eliminate) the ability of a user to access elements arranged within an interior of the isolation valve 102. Limiting (or eliminating) access to the elements arranged within the interior of the isolation valve 102 may in turn improve the reliability of the flow control arrangement 100, for example, by preventing tampering with inlet conduit 108 an the flow switch by the user. As will be appreciated by those of skill in the art in view of the present disclosure, tampering prevention can reduce (or eliminate) inadvertent change to the flow switch switch 212, providing the flow control arrangement 100 with a higher SIL rating than otherwise possible.

The inlet conduit 208 and the outlet conduit 210 are both seated in a wall of the housing 206. The first isolation valve 202, the flow switch 212, and the second isolation valve 204 are each arranged within an interior 226 of the housing 206. In this respect the first isolation valve 202 is connected to the inlet conduit 208, the first interconnect conduit 214 is connected to the first isolation valve 202 and is in selective fluid communication therethrough with the inlet conduit 208, and the flow switch 212 is connected to the first interconnect conduit 214 and is in fluid communication therethrough with the first isolation valve 202. In further respect, the second interconnect conduit 216 is connected to the flow switch 212 and is in fluid communication therethrough with the first interconnect conduit 214, the second isolation valve 204 is connected to the second interconnect conduit 216 and is in fluid communication therethrough with the flow switch 212, and the outlet conduit 210 is connected to the second isolation valve 204 and is in selective fluid communication therethrough with the first isolation valve 202 through the flow switch 212.

The inlet conduit 208 is with the fluid source 12 (shown in FIG. 1), the outlet conduit 210 is in fluid communication with the flow control device 26 (shown in FIG. 1), and that the fluid source 12 is in selective fluid communication with the flow control device 26 through the first isolation valve 202 and the second isolation valve 204. In this respect the first isolation valve 202 and the second isolation valve 204 have open positions, wherein the first isolation valve 202 and the second isolation valve 204 fluidly couple the outlet conduit 210 with the inlet conduit 208 such that the fluid source 12 is in fluid communication with the flow control device 26. When either (or both) the first isolation valve 202 and the second isolation valve 204 are in the closed position the outlet conduit 210 is fluidly separated from the inlet conduit 208, the fluid source 12 thereby fluidly separated from the flow control device 26. As will be appreciated by those of skill in the art in view of the present disclosure, closure of either (or both) the first isolation valve 202 and the second isolation valve 204 causes fluid separation of the outlet conduit 210 from the inlet conduit 208, allowing for fluid separation in unlikely event that either of the first isolation valve 202 and the second isolation valve 204 fails to close when closure is required.

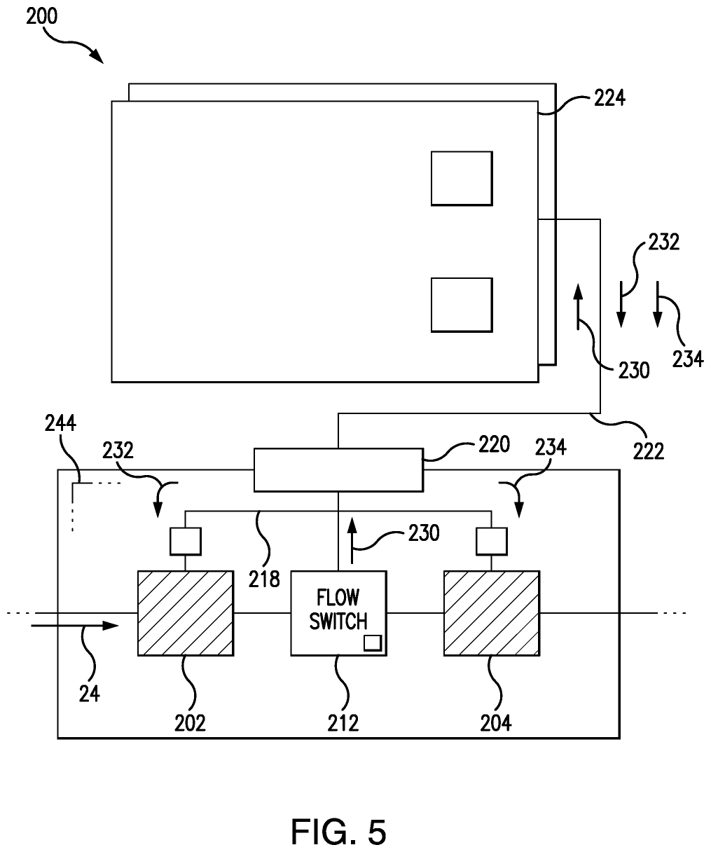

With reference to FIGS. 4 and 5, the flow switch 212 has a shutoff trigger 228 and is operatively connected to the first isolation valve 202 and the second isolation valve 204 to close when flow rate of fluid traversing the flow switch 212 rises above the shutoff trigger 228. When the flow rate of fluid traversing the flow switch 212 is less than the shutoff trigger 228, both the first isolation valve 202 and the second isolation valve 204 remain open. When flow rate of fluid traversing the flow switch 212 is greater than the shutoff trigger 228, the flow switch 212 causes both the first isolation valve 202 and the second isolation valve 204 to close. In this respect it is contemplated that the flow switch 212 provide a shutoff signal 230 (shown in FIG. 5) to the controller 224 when the flow rate of fluid through the flow switch 212 is greater than, e.g., rises above, the shutoff trigger 228. Responsive to receipt of the shutoff signal 230 from the flow switch 212, the controller 224 provides a first isolation valve closure signal 232 (shown in FIG. 5) and a first isolation valve closure signal 232 (shown in FIG. 5) to the first isolation valve 202 and the second isolation valve closure signal 234 to the second isolation valve 204.

As shown in FIG. 5, the shutoff signal 230 may be communicated to the controller 224 through the internal communication harness 218, the electrical connector 220, the external communication cable 222. In this respect it is contemplated that the controller 224 electrically connect the flow switch 212 to the first isolation valve 202 and the second isolation valve 204. For example, the electrical connector 220 may be seated in the wall of the housing 206 and connected to the controller 224 by the external communication cable 222. The internal communication harness 218 may be arranged within the interior 226 of the housing 206 and connect the electrical connector 220 with each of the first isolation valve 202, the second isolation valve 204, and the flow switch 212. The external communication cable 222 and the internal communication harness 218 may include dedicated conductors (e.g., electrically isolated from one another) to communicate the each of the shutoff signal 230, the first isolation valve closure signal 232, and the second isolation valve closure signal 234 between the flow switch 212 and the controller 224, between the controller 224 and the first isolation valve 202, and between the controller 224 and the second isolation valve 204, respectively. As will be appreciated by those of skill in the art in view of the present disclosure, employment of discrete conductors can provide a relatively high SIL rating to the flow control arrangement 200, for example, a SIL rating between 2 and 4 in certain examples of the present disclosure. As will also be appreciated by those of skill in the art in view of the present disclosure, other communication arrangements are possible and remain within the scope of the present disclosure.

As shown in FIG. 4, operative association of the flow switch 212 with the first isolation valve 202 and the second isolation valve 204 may be accomplished through a first solenoid 236, a second solenoid 238, a first relay 240, and a second relay 242. The first solenoid 236 and the second solenoid 238 may be arranged within the interior 226 of the housing 206 and operatively connected to the first isolation valve 202 and the second isolation valve 204, respectively. The first relay 240 and the second relay 242 may arranged outside of the housing 206, operatively associated with the controller 224 (e.g., included in the controller 224), and in communication with a power source to communicate the first isolation valve closure signal 232 to the first isolation valve 202 and the second isolation valve closure signal 234 to the second isolation valve 204 upon receipt of the shutoff signal 230. In certain examples, either (or both) the first solenoid 236 and the second solenoid 238 may be a latching solenoid. As will be appreciated by those of skill in the art in view of the present disclosure, employment of latching solenoids allows the first isolation valve 202 and the second isolation valve 204 to remain closed in the event that the rate of fluid flow through the flow switch 212 falls below the shutoff trigger 228, allowing the flow switch 212 to be arranged fluidly in series between the first isolation valve 202 and the second isolation valve 204. As will be appreciated by those of skill in the art in view of the present disclosure, other types of solenoids may be employed and remain within the scope of the present disclosure.

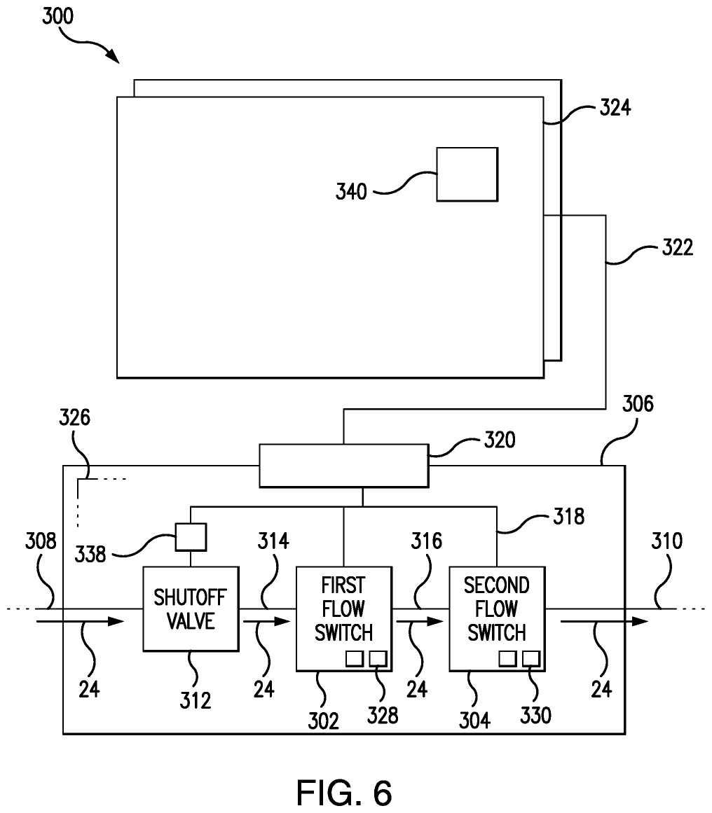

With reference to FIG. 6, a flow control arrangement 300 is shown. The flow control arrangement 300 is similar to the flow control arrangement 100 (shown in FIG. 1) and additionally includes a first flow switch 302 and a second flow switch 304. In the illustrated example the flow control arrangement 300 also includes a housing 306, an inlet conduit 308, an outlet conduit 310, an isolation valve 312, a first interconnect conduit 314, a second interconnect conduit 316, an internal communication harness 318, and an electrical connector 320, an external communication cable 322, and a controller 324. Although a particular arrangement is shown and described herein, it is to be understood and appreciated that other arrangements are possible and remain within the scope of the present disclosure.

The housing 306 seats the inlet conduit 308 and the outlet conduit 310. The housing 306 is further arranged between the fluid source 12 (shown in FIG. 1) and the gas box 14 (shown in FIG. 1) relative to a general direction of flow of the fluid 24, and encloses the first flow switch 302, the second flow switch 304, and the isolation valve 312. In certain examples, the housing 306 may be configured to be supported outside of the semiconductor processing system 10 (shown in FIG. 1). In accordance with certain examples, the housing 306 may include a tamperproof body 326. It is contemplated that, in certain examples, the housing 306 may be formed from a metallic material, such as stainless steel. It is also contemplated that, in accordance with certain examples, the housing 306 may include a weldment. As will be appreciated by those of skill in the art in view of the present disclosure, the tamperproof body 326 may limit (or eliminate) the ability of a user to access elements arranged within an interior of the housing 306. Limiting (or eliminating) access to elements arranged within the interior of the housing 306 in turn improves the reliability of the flow control arrangement 300, for example, by preventing unintended adjustment to the first flow switch 302 and/or the second flow switch 304. As will be appreciated by those of the skill in art of the present disclosure, limiting (or eliminating) risk of inadvertent adjustment of the first flow switch 302 and the second flow switch 304 can provide the flow control arrangement 300 with a higher SIL rating than other otherwise warranted by the arrangement.

The isolation valve 312 is connected to the inlet conduit 308 and connected to the first flow switch 302 by the first interconnect conduit 314, the first flow switch 302 and the second flow switch 304 being in selective fluid communication with the inlet conduit 308 through the isolation valve 312. The second interconnect conduit 316 is connected to the first flow switch 302, connects the second flow switch 304 to the first flow switch 302, and is fluidly coupled to the outlet conduit 310 by the second flow switch 304. The second flow switch 304 is connected to the second interconnect conduit 316, connects the second flow switch 304 to the outlet conduit 310, and fluidly couples to the outlet conduit 310 to the isolation valve 312 for selective fluid communication therethrough with the inlet conduit 308. It is contemplated that the inlet conduit 308 be in fluid communication with the fluid source 12 (shown in FIG. 1), that the outlet conduit 310 be in fluid communication with the flow control device 26 (shown in FIG. 1), and that the fluid source 12 be in selective fluid communication with the flow control device 26 through the isolation valve 312. In this respect the isolation valve 312 has an open position, wherein the isolation valve 312 fluidly couples the outlet conduit 310 to the inlet conduit 308 such that the fluid source 12 is in fluid communication with the flow control device 26, and a closed position, wherein the outlet conduit 310 is fluidly separated from the inlet conduit 308 such that the fluid source 12 is fluidly separated from the flow control device 26.

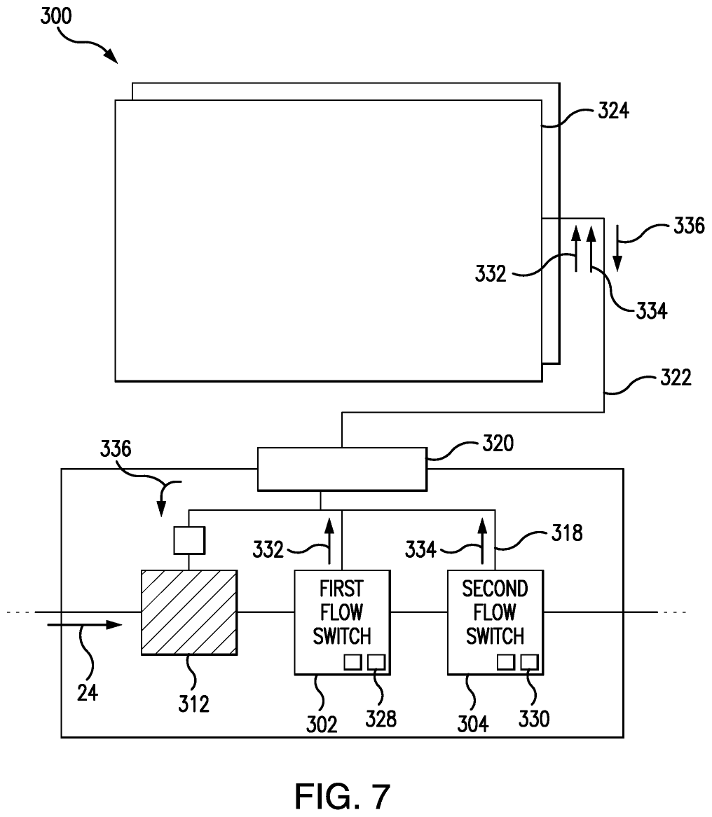

Referring to FIGS. 6 and 7, the first flow switch 302 has a first shutoff trigger 328 and is operatively connected to the isolation valve 312. The second flow switch 304 has a second shutoff trigger 330 and is also operatively connected to the isolation valve 312. As shown in FIG. 6, when the flow rate of the fluid 24 traversing the first flow switch 302 and the second flow switch 304 is less than the first shutoff trigger 328 and the second shutoff trigger 330, the isolation valve 312 remains open. As shown in FIG. 7, when flow rate of the fluid 24 traversing the first flow switch 302 rises above (and is greater) than the first shutoff trigger 328 or the second shutoff trigger 330, either (or both) the first flow switch 302 and the second flow switch 304 cause the isolation valve 312 to close. In this respect it is contemplated that the first flow switch 302 provide a first flow switch shutoff signal 332 and/or the second flow switch 304 provide a second flow switch shutoff signal 334 to the controller 324. Responsive to receipt of at least one of the first flow switch shutoff signal 332 and the second flow switch shutoff signal 334, the controller 324 provides an isolation valve closure signal 336 to the isolation valve 312, the isolation valve 312 in turn closing on receipt of the isolation valve closure signal 336.

In certain examples the second shutoff trigger 330 may be substantially equivalent to the first shutoff trigger 328. In such examples the second flow switch 304 provides redundancy to the flow control arrangement 300, the second flow switch 304 causing the isolation valve 312 to close in the unlikely event that the first flow switch 302 fails to provide the first shutoff trigger 328 when flow of fluid traversing the first flow switch 302 exceeds the first shutoff trigger 328. Similarly, provision of the first flow switch shutoff signal 332 by the first flow switch 302 ensures closure of the isolation valve 312 in the unlikely event that the second flow switch 304 fails to provide the second flow switch shutoff signal 334 when fluid flow traversing the second flow switch 304 exceeds the second shutoff trigger 330. As will be appreciated by those of skill in the art in view of the present disclosure, the redundancy provided by the first shutoff trigger 328 and the second shutoff trigger 330 being substantially equivalent to one another may provide the flow control arrangement 300 with a higher SIL rating than otherwise possible.

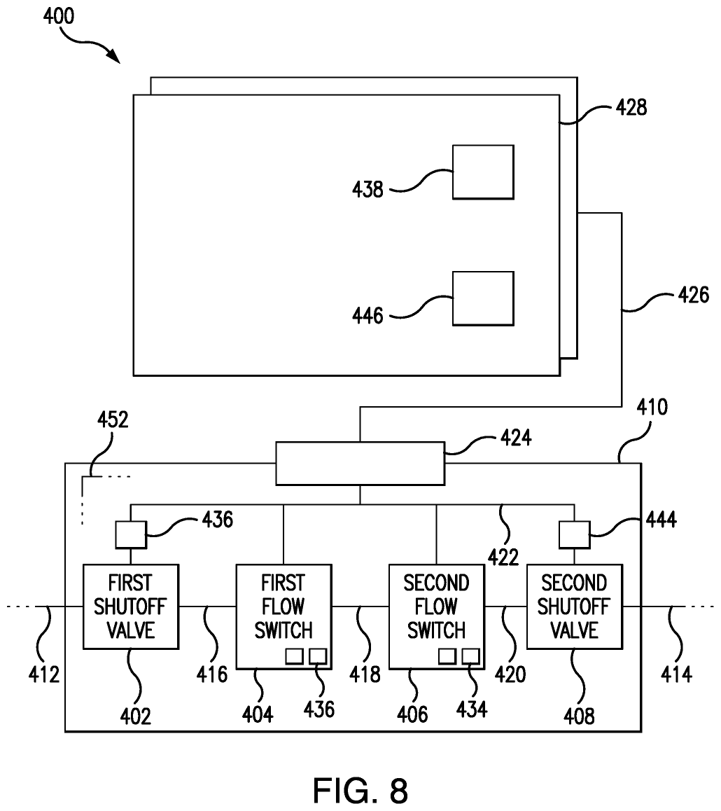

In certain examples, one of the first shutoff trigger 328 and the second shutoff trigger 330 may be smaller than the other the first shutoff trigger 328 and the second shutoff trigger 330. The smaller of the first shutoff trigger 328 and the second shutoff trigger 330 may be employed to verify closure of the isolation valve 312, failure of flow through the one of the first flow switch 302 and the second flow switch 304 having the smaller of the first shutoff trigger 328 and the second shutoff trigger 330 providing indication of leakage through the isolation valve 312 subsequent to closure in such examples. For example, the controller 324 may understand receipt of a shutoff signal provided by the one of the first flow switch 302 and the second flow switch 304 having the smaller of the first shutoff trigger 328 and the second shutoff trigger 330 as indication of normal operation when no closure signal has been provided to the isolation valve 312, and indication of abnormal operation subsequent to provision of the isolation valve closure signal 336 (shown in FIG. 8). As will be appreciated by those of skill in the art in view of the present disclosure, employment of discrete conductors can provide a relatively high SIL rating to the flow control arrangement 300, for example, a SIL rating between 2 and 4 in certain examples of the present disclosure. As will also be appreciated by those of skill in the art in view of the present disclosure, this may also provide the flow control arrangement 300 with a higher SIL rating than otherwise possible.

In certain examples the first flow switch shutoff signal 332 and the second flow switch shutoff signal 334 may be communicated to the controller 324 through the internal communication harness 318, the electrical connector 320, the external communication cable 322. In this respect the controller 324 may electrically connect both the first flow switch 302 and the second flow switch 304 to the isolation valve 312. For example, the electrical connector 320 may be seated in the wall of the housing 306 and connected therethrough to the controller 324 by the external communication cable 322. The internal communication harness 318 may be arranged in the housing 306 and in turn connect the electrical connector 320 to each of the isolation valve 312, the first flow switch 302, and the second flow switch 304. In accordance with certain examples, the external communication cable 322 and the internal communication harness 318 may both include dedicated conductors (e.g., electrically isolated from one another) to communicate the each of the first shutoff trigger 328, the second shutoff trigger 330, and the isolation valve closure signal 336 between the first flow switch 302 and the controller 324, the second flow switch 304 and the controller 324, and the controller 324 and the isolation valve 312. As will be appreciated by those of skill in the art in view of the present disclosure, other communication arrangements are possible and remain within the scope of the present disclosure.

Operative association of the first flow switch 302 and the second flow switch 304 with the isolation valve 312 may be accomplished through a solenoid 338 and a relay 340. In this respect the solenoid 338 may be arranged in the housing 306 and operatively connected to the isolation valve 312. The relay 340 may be arranged outside of the housing 306 (e.g., as part of the controller 324), operatively associated with the controller 324, and in communication with a power source to communicate the isolation valve closure signal 336 to the isolation valve 312. As above, it is contemplated that the solenoid 338 may be a latching solenoid, allowing the isolation valve 312 to remain closed when fluid flow through the first flow switch 302 and the second flow switch 304 ceases subsequent to closure of the isolation valve 312.

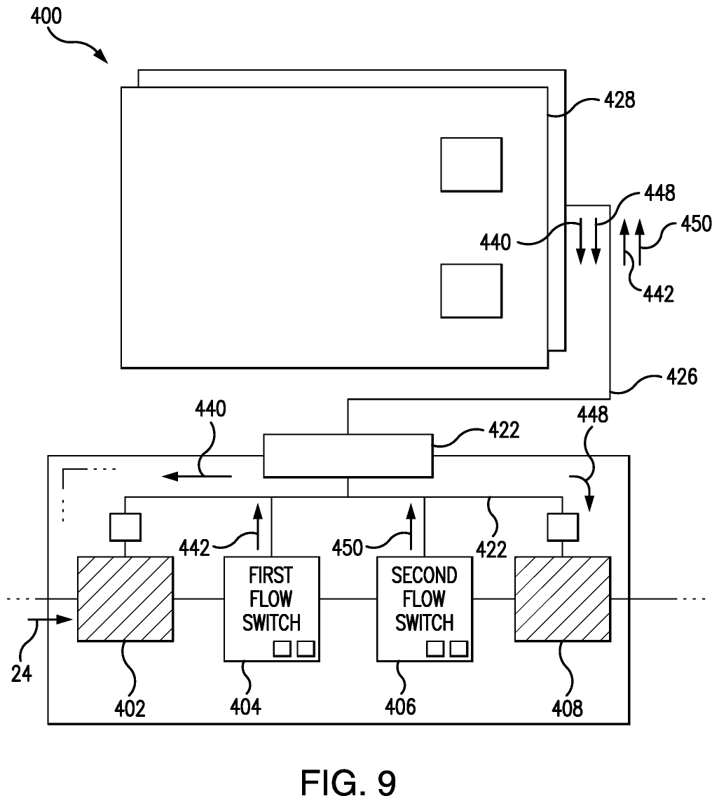

With reference to FIGS. 8 and 9, a flow control arrangement 400 is shown. The flow control arrangement 400 is similar to the flow control arrangement 100 (shown in FIG. 1) and additionally includes a first isolation valve 402, a first flow switch 404, a second flow switch 406, and a second isolation valve 408. In the illustrated example the flow control arrangement 400 also includes a housing 410, an inlet conduit 412, an outlet conduit 414, a first interconnect conduit 416, a second interconnect conduit 418, a third interconnect conduit 420, an internal communication harness 422, an electrical connector 424, an external communication cable 426, and a controller 428. Although a particular arrangement is shown and described herein it is to be understood and appreciated that other examples are possible and remain within the scope of the present disclosure.

As shown in FIG. 8, the inlet conduit 412 and the outlet conduit 414 are seated in the housing 410. The housing 410 is further arranged between the fluid source 12 (shown in FIG. 1) and the gas box 14 (shown in FIG. 1) relative to the general direction flow of the fluid 24 from the fluid source 12 and the gas box 14, may be configured to be supported outside of the semiconductor processing system 10 (shown in FIG. 1). In certain examples, the housing 410 may include a tamperproof body 452. In accordance with certain examples, the housing 410 may be formed from a metallic material, such as stainless steel. It is also contemplated that, in accordance with certain examples, the housing 410 may include a weldment. As will be appreciated by those of skill in the art in view of the present disclosure, the tamperproof body 452 may limit (or eliminate) the ability of a user to access elements arranged within an interior of the housing 410. Limiting (or eliminating) access to the elements arranged within the interior of the housing 410 may in turn improve the reliability of the flow control arrangement 400, for example, by increasing the SIL rating of the flow control arrangement 400.

The inlet conduit 412 fluidly couples the flow control arrangement 400 to the fluid source 12 (shown in FIG. 1) to receive the fluid 24 from the fluid source 12. The outlet conduit 414 fluidly couples the flow control arrangement 400 to the flow control device 26 (shown in FIG. 1) to communication the fluid 24 to the flow control device 26. Communication of the fluid 24 from the fluid source 12 to the flow control device 26 through the flow control arrangement 400 is selective according to cooperation of the first flow switch 404 and the second flow switch 406 with the first isolation valve 402 and the second isolation valve 408.

The first isolation valve 402 is connected to the inlet conduit 412 and couples the first interconnect conduit 416 to the inlet conduit 412. The first isolation valve 402 has an open position and a closed position. As shown in FIG. 8, when in the open position, the first isolation valve 402 fluidly couples the first interconnect conduit 416 to the inlet conduit 412 and fluidly couple the outlet conduit 414 to the inlet conduit 412 in cooperation with the second isolation valve 408. As shown in FIG. 9, when in the closed position the first isolation valve 402 fluidly separates the first interconnect conduit 416 from the inlet conduit 412, no fluid communication occurring therethrough. As will be appreciated by those of skill in the art in view of the present disclosure, the first isolation valve 402 may fluidly separate the first interconnect conduit 416 from the inlet conduit 412 irrespective of whether the second isolation valve 408 is closed. Fluidly separating the first interconnect conduit 416 from the inlet conduit 412 irrespective of whether the second isolation valve 408 is closed provides redundancy to the flow control arrangement 400, increasing the SIL rating of the flow control arrangement 400 by ceasing flow of the fluid 24 in the unlikely event that the first isolation valve 402 fails to close. Examples of suitable isolation valves include D211 G1/8 DN2.0 solenoid valves, available from Jaksa d.o.o. of Ljubljana, Slovenia.

With continuing reference to FIG. 8, the first interconnect conduit 416 is connected to the first isolation valve 402 and couples the first flow switch 404 to the first isolation valve 402. In certain examples, the first interconnect conduit 416 may be connected to the first isolation valve 402 without a fitting or fastener, for example by a welded joint or connection, reducing (or eliminating) risk of fluid leakage within the housing 410 at the connection. In accordance with certain examples, the first flow switch 404 may be connected to the first interconnect conduit 416 without a fitting of fastener, for example also by a welded joint, also reducing (or eliminating) risk of fluid leaking within the housing 410 at the connection. As will be appreciated by those of skill in the art in view of the present disclosure, the first flow switch 404 may be directly connected to the first isolation valve 402, such as at a welded joint or connection, and remain within the scope of the present disclosure.

The first flow switch 404 is operatively connected to at least one of the first isolation valve 402 and the second isolation valve 408. In this respect the first flow switch 404 has a first shutoff trigger 430 (e.g., a mass or volumetric flow rate) above which the first flow switch 404 causes the at least one of the first isolation valve 402 and the second isolation valve 408 to close. In certain examples, the first flow switch 404 may be operatively connected to the first isolation valve 402 to close the first isolation valve 402 when flow rate of the fluid 24 traversing the first flow switch 404 is greater than (e.g., rises above) the first shutoff trigger 430. In accordance with certain examples, the first flow switch 404 may be operatively connected to the second isolation valve 408 to switch a to close the second isolation valve 408 when flow rate of the fluid 24 traversing the first flow switch 404 is greater than the first shutoff trigger 430. It is also contemplated that, in accordance with certain examples, the first flow switch 404 may be operatively connected to both the first isolation valve 402 and the second isolation valve 408 to close both the first isolation valve 402 and the second isolation valve 408 when flow rate of the fluid 24 traversing the first flow switch 404 is greater than the first shutoff trigger 430. As will be appreciated by those of skill in the art in view of the present disclosure, operative connection of the first flow switch 404 to both the first isolation valve 402 and the second isolation valve 408 may increase the SIL rating of the flow control arrangement 400, such as to a SIL rating of between 2 and 4 in certain examples. Examples of suitable flow switches include FS10A flow switches, available from Fluid Components International LLC of San Marcos, California.

The second interconnect conduit 418 is similar to the first interconnect conduit 416, is additionally connected to the first flow switch 404, and further couples the second flow switch 406 to the first flow switch 404. In certain examples, the second interconnect conduit 418 may be connected to the first flow switch 404 without a fitting or fastener, for example by a welded joint or connection, reducing (or eliminating) risk of fluid leakage within the housing 410 at the connection. In accordance with certain examples, the second flow switch 406 may be connected to the second interconnect conduit 418 without a fitting of fastener, for example also by a welded joint or connection, also reducing (or eliminating) risk of fluid leakage within the housing 410 at the connection. As will be appreciated by those of skill in the art in view of the present disclosure, the second flow switch 406 may be directly connected to the first flow switch 404, such as at a welded joint, and remain within the scope of the present disclosure.

The second flow switch 406 is similar to the first flow switch 404, additionally couples the second isolation valve 408 to the first flow switch 404 and therethrough to the first isolation valve 402, and is further operatively connected to at least one of the first isolation valve 402 and the second isolation valve 408. It is contemplated that the second flow switch 406 have a second shutoff trigger 434 that, when flow rate of the fluid 24 is greater than (e.g., rises above) the second shutoff trigger 434, causes the second flow switch 406 to close the at least one of the first isolation valve 402 and the second isolation valve 408. In certain examples, the second flow switch 406 may be operatively connected to the first isolation valve 402 to close the first isolation valve 402 when the flow rate of the fluid 24 traversing the second flow switch 406 is greater the second shutoff trigger 434. In accordance with certain examples, the second flow switch 406 may be operatively connected to the second isolation valve 408 to close the second isolation valve 408 when the flow rate of the fluid 24 traversing the second flow switch 406 is greater than the second shutoff trigger 434. It is also contemplated that, in accordance with certain examples, the second flow switch 406 may be operatively connected to both the first isolation valve 402 and the second isolation valve 408 to close both the first isolation valve 402 and the second isolation valve 408 when the flow rate of the fluid 24 traversing the first flow switch 404 is greater than the first shutoff trigger 430. As will be appreciated by those of skill in the art in view of the present disclosure, operative connection of the second flow switch 406 to both the first isolation valve 402 and the second isolation valve 408 may further increase the SIL rating of the flow control arrangement 400, such as to a SIL rating of between 2 and 4 in certain examples.

The third interconnect conduit 420 is also similar to the first interconnect conduit 416, is additionally connected to the second flow switch 406, and further couples the second isolation valve 408 to the second flow switch 406. In certain examples, the third interconnect conduit 420 may be connected to the second flow switch 406 without a fitting or fastener, for example by a welded joint or connection, reducing (or eliminating) risk of fluid leakage within the housing 410 at the connection. In accordance with certain examples, the second isolation valve 408 may be connected to the third interconnect conduit 420 without a fitting of fastener, for example also by a welded joint, also reducing (or eliminating) risk of fluid leakage within the housing 410 at the connection. As will be appreciated by those of skill in the art in view of the present disclosure, the second isolation valve 408 may be directly connected to the second flow switch 406, such as at a welded joint or connection, and remain within the scope of the present disclosure.

The second isolation valve 408 is similar to the first isolation valve, is additionally connected to the third interconnect conduit 420, and further couples the outlet conduit 414 third interconnect conduit 420 and therethrough to the first isolation valve 402 for selective fluid communication with the inlet conduit 412. It is contemplated that the second isolation valve 408 have an open position and a closed position. As shown in FIG. 8, when in the open position the second isolation valve 408 fluidly couples the outlet conduit 414 to the third interconnect conduit 420 to communicate the fluid 24 between the inlet conduit 412 and the outlet conduit 414 in cooperation with the first isolation valve 402. As shown in FIG. 9, when in the closed position, the second isolation valve 408 fluidly separates the outlet conduit 414 from the third interconnect conduit 420, the outlet conduit 414 thereby being fluidly separated from the inlet conduit 412. As will be appreciated by those of skill in the art in view of the present disclosure, the second isolation valve 408 may fluidly separate the outlet conduit 414 from the third interconnect conduit 420 independent of whether the first isolation valve 402 is open or closed, also providing redundancy to the flow control arrangement 400 and further increasing the SIL rating of the flow control arrangement 400.

It is contemplated that operative association of the first flow switch 404 and the second flow switch 406 with the first isolation valve 402 and the second isolation valve 408 may be through the controller 428. In this respect the controller 428 is arranged outside of the housing 410 and is connected by the external communication cable 426 to the electrical connector 424. The electrical connector 424 is seated in the housing 410 and is connected to internal communication harness 422. The internal communication harness 422 is arranged in the housing 410 and is in turn connected to each of the first isolation valve 402, the first flow switch 404, the second flow switch 406, and the second isolation valve 408. As will be appreciated by those of skill in the art in view of the present disclosure, other connectivity arrangements are possible and remain within the scope of the present disclosure.

With continuing reference to FIG. 8, in certain examples, the first isolation valve 402 may include a first solenoid 436 and the controller 428 may include a first relay 438. The first solenoid 436 may be arranged in the housing 410 and operatively connected to the first isolation valve 402 to close the first isolation valve 402 upon receipt of a first isolation valve closure signal 440 provided by the first relay 438. The controller 428 may be operatively connected to the first relay 438 to close the first relay 438 upon receipt of a first flow switch shutoff signal 442, which may be provided by the first flow switch 404 when flow rate of the fluid 24 traversing the first flow switch 404 is greater than the first shutoff trigger 432. The first solenoid 436 may include a latching solenoid, the first isolation valve 402 remaining closed upon cessation of the first flow switch shutoff signal 442 and/or the first isolation valve closure signal 440. As will be appreciated by those of skill in the art in view of the present disclosure, other operative connection arrangements between the first flow switch 404 and one or more of the first isolation valve 402 and the second isolation valve 408 and remain within the scope of the present disclosure.

In certain examples, the second isolation valve 408 may include a second solenoid 444 and the controller 428 may include a second relay 446. The second solenoid 444 may be arranged in the housing 410. The second solenoid 444 may further be operatively connected to the first isolation valve 402 to close the first isolation valve 402 upon receipt of a second isolation valve closure signal 448 provided by the second relay 446. The controller 428 may be operatively connected to the second relay 446 to close the second relay 446 upon receipt of a second flow switch shutoff signal 450 provided by the second flow switch 406 when flow rate of the fluid 24 traversing the second flow switch 406 is greater than the second shutoff trigger 434. The second solenoid 444 may include a latching solenoid, the second isolation valve 408 remaining closed upon cessation of the second flow switch shutoff signal 450 and/or the second isolation valve closure signal 448. As will be appreciated by those of skill in the art in view of the present disclosure, other operative connection arrangements between the second flow switch 406 and one or more of the first isolation valve 402 and the second isolation valve 408 and remain within the scope of the present disclosure.

In certain examples, the second shutoff trigger 434 may be equivalent (e.g., matched) to the first shutoff trigger 432. As will be appreciated by those of skill in the art in view of the present disclosure, examples of the flow control arrangement 400 wherein the second shutoff trigger 434 is equivalent to the first shutoff trigger 432 provides redundant shutoff triggering to the first isolation valve 402 and the second isolation valve 408 to the flow control arrangement 400. Redundant shutoff triggering can reduce (or eliminate) the likelihood that the flow control arrangement 400 cease flow of the fluid 24 (shown in FIG. 1) when flow exceeds that to which the vent flow 30 (shown in FIG. 1) and/or the inert gas flow 44 (shown in FIG. 1) are sized, potentially increasing the SIL rating of the flow control arrangement 400 to a higher rating than otherwise possible.

In accordance with certain examples, the second shutoff trigger 434 may be different than (e.g., unmatched) the first shutoff trigger 432. For example, the second shutoff trigger 434 may be smaller than the first shutoff trigger 432. Alternatively, the second shutoff trigger 434 may be greater than the first shutoff trigger 432. In such examples difference between the first shutoff trigger 432 and the second shutoff trigger 434 may allow for determining whether closure of either (or both) the first isolation valve 402 and the second isolation valve 408 is successful once fluid flow of the fluid 24 (shown in FIG. 1) exceeds the larger of the first shutoff trigger 432 and the second shutoff trigger 434. As will be appreciated by those of skill in the art in view of the present disclosure, monitoring closure of the first isolation valve 402 and/or the second isolation valve 408 can also improve the reliability of the flow control arrangement 400, also providing the flow control arrangement 400 with a higher SIL rating than otherwise possible.

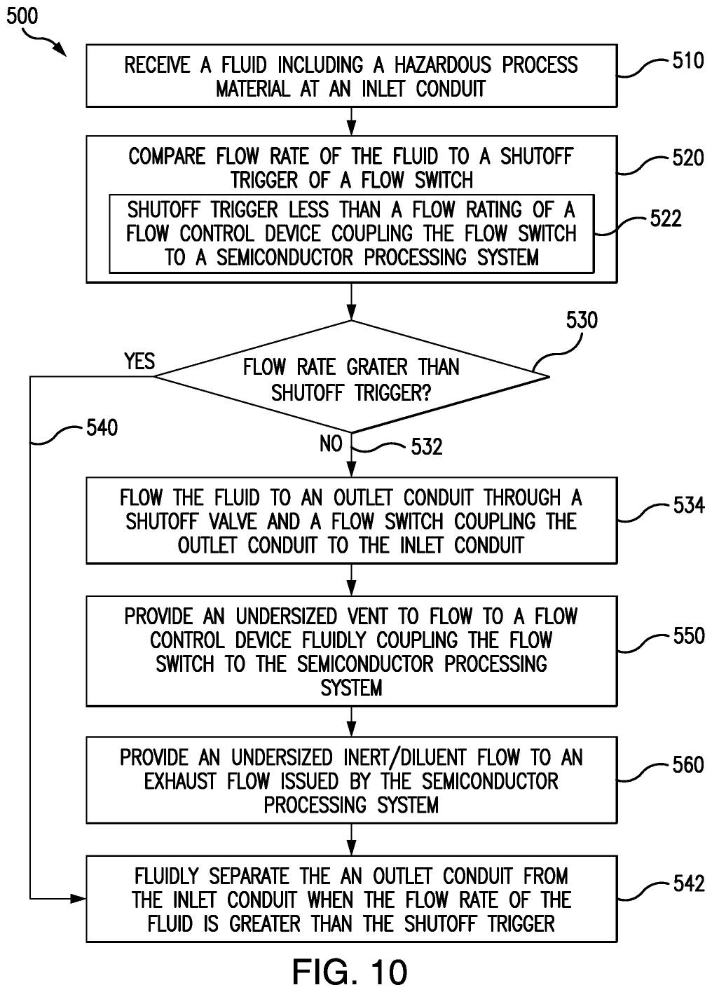

With reference to FIG. 10, the flow control method 500 is shown. The flow control method 500 includes receiving fluid, e.g., the fluid 24 (shown in FIG. 1), at a flow control arrangement, e.g., the flow control arrangement 100 (shown in FIG. 1), as shown with box 510. Flow rate of the fluid is compared to a shutoff trigger of a flow switch of the flow switch arrangement, e.g., the shutoff trigger 126 (shown in FIG. 2) of the flow switch 104 (shown in FIG. 2), as shown with box 520. It is contemplated that the shutoff trigger may be less than a flow rating of a flow control device coupling the flow switch to a semiconductor processing system, e.g., the flow rating 28 (shown in FIG. 1) of the flow control device 26 (shown in FIG. 1) coupled to the semiconductor processing system 10 (shown in FIG. 1), as shows with box 522.

When the flow rate of the fluid is less than the shutoff trigger of the flow switch, the fluid is flowed to the outlet conduit of the flow control arrangement to the semiconductor processing system, as shown with box 530, arrow 532, box 534. When the flow rate of the fluid is greater than the shutoff trigger, the outlet conduit is fluidly separated from the inlet conduit by closing an isolation valve coupling the flow switch to the inlet conduit, e.g., the isolation valve 102 (shown in FIG. 2), as shown with arrow 540 and box 542. It is contemplated that an undersized (relative to the flow rating of the flow control device) vent flow be provided to the semiconductor processing system, as shown with box 550. For example, the vent flow 30 (shown in FIG. 1) may be undersized relative to the flow rating 28 (shown in FIG. 1) of the flow control device 26 (shown in FIG. 1). It is also contemplated that an undersized inert/diluent fluid flow (relative to the flow rating of the flow control device) may be provided to an exhaust flow issued by the semiconductor processing system, as shown with box 560. For example, the inert/diluent fluid flow 42 may be undersized relative to the flow rating 28 of the flow control device 26.

Vent flows and inert/diluent fluid flows may be provided to semiconductor processing system to limit (or eliminate) risk associated with fluid flows containing HPMs provided to the semiconductor processing system. Such fluid flows may be sized to correspond to the highest flow rate of the fluid to the semiconductor processing system that may be expected during operation of the semiconductor processing system, such as the flow rating of a flow control device fluidly coupling the fluid source to the semiconductor processing system, the vent flow and/or the inert/diluent fluid flow thereby ensuring limiting (or eliminating) hazards associated with the fluid. Cost associated with the provision of such vent flows and inert/diluent fluids corresponds with the flow rate of the vent flow and the inert/diluent fluid flow, greater flow rates associated with greater cost.

In certain examples of the present disclosure a flow control arrangement is provided including a flow switch and an isolation valve. The flow switch has a shutoff trigger and is operatively connected to the isolation valve to close the isolation valve when flow rate of a fluid containing a hazardous material (e.g., an HPM) rises above the shutoff trigger of the flow switch. Advantageously, the flow switch may improve safety of the semiconductor processing system for example, by reducing (or eliminating) probability that the semiconductor processing system receive the fluid at a flow rating corresponding to the flow rating of the flow control device, like in the unlikely situation that the flow control fail in a fully open position. For example, flow control arrangements described herein may have SIL rating of 1, 2, 3 or event 4—though flow control arrangements described herein may be unrated and remain within the scope of the current disclosure. To further advantage, flow rate of a vent flow and/or an inert/diluent fluid flow provided to the semiconductor processing system may be sized to correspond to the shutoff trigger of the flow switch, and not the flow rating of the flow control device, limiting cost of operating the semiconductor processing system.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises,” “comprising,” “includes,” and/or “including.” when used in this specification, specify the presence of stated features, integers, steps, operations, elements, and/or components, but do not preclude the presence or addition of one or more other features, integers, steps, operations, element components, and/or groups thereof. The term “about” is intended to include the degree of error associated with measurement of the particular quantity based upon the equipment available at the time of filing the application.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

1. A flow control arrangement, comprising:
a housing seating an inlet conduit and an outlet conduit;
an isolation valve arranged within the housing and connected to the inlet conduit; and
a flow switch with a shutoff trigger arranged within the housing and connected to the isolation valve, the flow switch coupling the isolation valve to the outlet conduit, and the flow switch further operatively connected to the isolation valve to close the isolation valve when flow traversing the isolation valve is greater than the shutoff trigger.

2. The flow control arrangement of claim 1, wherein the housing includes a tamperproof body enclosing the isolation valve and the flow switch.

3. The flow control arrangement of claim 1, further comprising:
a relay outside of the housing and operatively associated with the flow switch; and
a solenoid electrically connected to the relay and arranged in the housing, wherein the solenoid is operatively connected to the isolation valve to close the isolation valve when a flow rate of a fluid traversing the flow switch is greater than the shutoff trigger.

4. The flow control arrangement of claim 1, further comprising:
an internal communication harness arranged in the housing and connected to the isolation valve and the flow switch;
an electrical connector connected to the internal communication harness and seated in a wall of the housing;
an external communication cable connected to the electrical connector and arranged outside of the housing; and
a controller connected to the external communication cable and operably connecting the flow switch to the isolation valve.

5. The flow control arrangement of claim 1, further comprising a controller arranged outside of the housing and operably connecting the flow switch to the isolation valve.

6. The flow control arrangement of claim 5, wherein the controller includes a safety programmable logic controller device.

7. The flow control arrangement of claim 5, wherein the controller comprises a processor disposed in communication with a memory including a non-transitory machine-readable medium having a plurality of program modules recorded thereon containing instructions that, when read by the processor, cause the processor to:
receive a shutoff signal from the flow switch; and
provide a closure signal to the isolation valve upon receipt of the shutoff signal from the flow switch.

8. The flow control arrangement of claim 1, wherein the isolation valve is a first an isolation valve and further comprising a second isolation valve, wherein the second isolation valve is arranged in the housing and couples the first isolation valve to the outlet conduit, and wherein the second isolation valve is operably associated with the flow switch.

9. The flow control arrangement of claim 8, further comprising:
a first relay outside the housing and operatively associated with the flow switch;
a first solenoid electrically connected to the first relay, arranged in the housing, and operatively connected to the first isolation valve to close the first isolation valve when a flow rate of fluid traversing the flow switch is greater than the shutoff trigger;
a second relay outside the housing and operatively associated with the flow switch; and
a second solenoid electrically connected to the second relay, arranged in the housing, and operatively connected to the second isolation valve to close the second isolation valve when the flow ate of the fluid traversing the flow switch is greater than the shutoff trigger.

10. The flow control arrangement of claim 8, further comprising:
an internal communication harness arranged in the housing and connected to the first isolation valve, the flow switch, and the second isolation valve;
an electrical connector connected to the internal communication harness and seated in a wall of the housing;
an external communication cable connected to the electrical connector and arranged outside of the housing; and
a controller connected to the external communication cable and operably connecting the flow switch to the first isolation valve and the second isolation valve.

11. The flow control arrangement of claim 10, wherein the controller comprises a processor disposed in communication with a memory including a non-transitory machine-readable medium having a plurality of program modules recorded thereon containing instructions that, when read by the processor, cause the processor to:
receive a shutoff signal from the flow switch;
provide a first closure signal to the first isolation valve upon receipt of the shutoff signal from the flow switch; and
provide a second closure signal to the second isolation valve upon receipt of the shutoff signal from the flow switch.

12. The flow control arrangement of claim 1, wherein the flow switch is a first flow switch and further comprising a second flow switch, wherein the second flow switch couples the first flow switch to the outlet conduit and is operably connected to the isolation valve.

13. The flow control arrangement of claim 12, wherein the shutoff trigger is a first shutoff trigger and the second flow switch has a second shutoff trigger, wherein the second shutoff trigger is equivalent to the first shutoff trigger.

14. The flow control arrangement of claim 12, wherein the shutoff trigger is a first shutoff trigger and the second flow switch has a second shutoff trigger, wherein the second shutoff trigger is greater than or less than the first shutoff trigger.

15. The flow control arrangement of claim 12, further comprising a controller arranged outside of the housing, wherein the controller operably connects the first flow switch and the second flow switch to the isolation valve.

16. The flow control arrangement of claim 1, wherein the isolation valve is a first isolation valve and the flow switch is a first flow switch, the flow control arrangement further comprising:
a second flow switch connected to the first flow switch and coupled by the first flow switch to the first isolation valve; and
a second isolation valve connected to the second flow switch and fluidly coupled therethrough to the first flow switch, the second isolation valve connecting the outlet conduit to the second flow switch, wherein the second flow switch is operably connected to at least one of the first isolation valve and the second isolation valve.

17. The flow control arrangement of claim 16, wherein the first flow switch is operably connected to the first isolation valve and the second isolation valve, wherein the second flow switch is operably connected to the first isolation valve and the second isolation valve.

18. The flow control arrangement of claim 16, wherein one of the first flow switch and the second flow switch is operably connected to only one of the first isolation valve and the second isolation valve.

19. A semiconductor processing system, comprising:
a gas box with a flow control device, the flow control device having a flow rating;
a flow control arrangement as recited in claim 1, wherein the flow control arrangement is arranged outside of the gas box, wherein the flow control device is connected to the outlet conduit and therethrough to the inlet conduit of the flow control arrangement;
a process chamber including a substrate support connected to the flow control device and fluidly coupled therethrough to the flow control arrangement; and
a fluid source connected to the inlet conduit of the flow control arrangement and therethrough to the process chamber, wherein the fluid source comprises a hazardous process material.

20. The semiconductor processing system of claim 19, further comprising a vent source connected to the gas box and providing a vent flow to the gas box, wherein the vent flow is undersized relative to the flow rating of the flow control device.

21. The semiconductor processing system of claim 19, further comprising:
an exhaust source connected to the process chamber and receiving an exhaust flow from the process chamber; and
an inert/diluent fluid source connected exhaust source providing an inert/diluent fluid with an inert/diluent flow rate to the exhaust flow, wherein the inert/diluent fluid flow rate is undersized relative to the flow rating of the flow control device.

22. A flow control method, comprising:
at a flow control arrangement including a housing seating an inlet conduit and an outlet conduit, an isolation valve arranged in the housing and connected to the inlet conduit, a flow switch with a shutoff trigger arranged in the housing and connected to the isolation valve, the flow switch coupling the isolation valve to the outlet conduit, the flow switch operatively connected to the isolation valve,
receiving a fluid including an HPM at the inlet conduit;
comparing a flow rate of the fluid to the shutoff trigger;
flowing the fluid to the outlet conduit through the isolation valve and the flow switch when the flow rate of the fluid is less than the shutoff trigger;
fluidly separating the outlet conduit from the inlet conduit using the isolation valve when the flow rate of the fluid is greater than the shutoff trigger;
wherein the shutoff trigger is less than a flow rating of a flow control device coupling the flow switch to a semiconductor processing system; and
whereby at least one of a vent flow provided to a gas box of the semiconductor processing system and/or an inert/diluent fluid flow provided to an exhaust flow issued by a process chamber of the semiconductor processing system is undersized relative to a flow control device arranged in the gas box and fluidly coupling the flow control arrangement to the process chamber.
